(19) United States
(12) Patent Application Publication
(10) Pub. No.: US 2025/0006751 A1
(43) Pub. Date: Jan. 2, 2025

(54) IMAGING DEVICE AND ELECTRONIC APPARATUS

(71) Applicant: SONY SEMICONDUCTOR SOLUTIONS CORPORATION, KANAGAWA (JP)

(72) Inventor: YOSHIMITSU NAKASHIMA, KANAGAWA (JP)

(21) Appl. No.: 18/705,846

(22) PCT Filed: Sep. 14, 2022
(86) PCT No.: PCT/JP2022/034422

§ 371 Date: Apr. 29, 2024

(30) Foreign Application Priority Data
Nov. 5, 2021 (JP) 2021-181454

(51) Int. Cl. H01L 27/146

(52) U.S. Cl. CPC H01L 27/14607; H01L 27/14645

(57) ABSTRACT

An imaging device of an embodiment of the present disclosure includes a semiconductor substrate, multiple first pixels, and multiple second pixels. The semiconductor substrate includes a first surface and a second surface that are opposed to each other, and includes a pixel array unit in which multiple unit pixels are arranged in a matrix. The multiple first pixels are each provided in corresponding one of the multiple unit pixels. The multiple second pixels are each provided in corresponding one of the multiple unit pixels and convert a smaller amount of charge per unit time than the multiple first pixels. The multiple second pixels are each disposed in corresponding one of the unit pixels to allow the multiple second pixels to be equal to each other in distance from a center of the pixel array unit, on the basis of respective positions, in the pixel array unit, of the multiple unit pixels in which the respective second pixels are provided, in a planar view.

### TECHNICAL FIELD

The present disclosure relates to, for example, an imaging device including multiple pixels with different sensitivities in a unit pixel, and to an electronic apparatus provided with this imaging device.

### BACKGROUND ART

For example, PTL 1 discloses an imaging device that has two types of photoelectric converters provided in a unit pixel. The photoelectric converters differ in an amount of charge to be converted per unit time. The imaging device performs signal processing using the difference in sensitivity between the photoelectric converters.

### CITATION LIST

### Patent Literature

PTL 1: Japanese Unexamined Patent Application Publication No. 2017-163010

### SUMMARY OF THE INVENTION

Incidentally, improvement of image quality is demanded in such an imaging device intended to expand a dynamic range.

It is desirable to provide an imaging device and an electronic apparatus that make it possible to improve image quality.

An imaging device as an embodiment of the present disclosure includes a semiconductor substrate, multiple first pixels, and multiple second pixels. The semiconductor substrate includes a first surface and a second surface that are opposed to each other, and includes a pixel array unit in which multiple unit pixels are arranged in a matrix. The multiple first pixels are each provided in corresponding one of the multiple unit pixels. The multiple second pixels are each provided in corresponding one of the multiple unit pixels and convert a smaller amount of charge per unit time than the multiple first pixels. The multiple second pixels are each disposed in corresponding one of the unit pixels to allow the multiple second pixels to be equal to each other in distance from a center of the pixel array unit, on the basis of respective positions, in the pixel array unit, of the multiple unit pixels in which the respective second pixels are provided, in a planar view.

An electronic apparatus of an embodiment of the present disclosure includes the imaging device of the embodiment of the present disclosure described above.

The imaging device of the embodiment of the present disclosure and the electronic apparatus of the embodiment of the present disclosure each include the pixel array unit in which the multiple unit pixels are arranged in a matrix. The multiple unit pixels each include the first pixel and the second pixel. The second pixel converts a smaller amount of charge per unit time than the first pixel. The second pixels each provided in corresponding one of the multiple unit pixels are each disposed in corresponding one of the unit pixels to allow the second pixels to be equal to each other in distance from the center of the pixel array unit, on the basis of the respective positions, in the pixel array unit, of the multiple unit pixels in which the respective second pixels are provided, in a planar view.

### BRIEF DESCRIPTION OF THE DRAWINGS

FIG. 1 is a block diagram illustrating a configuration example of functions of an imaging device according to one embodiment of the present disclosure.

FIG. 2 is a block diagram illustrating a configuration example of functions of an imaging device as a first modification example of one embodiment.

FIG. 3 is a block diagram illustrating a configuration example of functions of an imaging device as a second modification example of one embodiment.

FIG. 4 is a circuit diagram illustrating a circuit configuration of the imaging device illustrated in FIG. 1, etc.

FIG. 5 is a schematic planar diagram illustrating an example of a planar configuration of a unit pixel of the imaging device illustrated in FIG. 1, etc.

FIG. 6 is a schematic cross-sectional view of an example of a configuration of the imaging device along line I-I′ illustrated in FIG. 5.

FIG. 7 is a schematic planar view of an example of a layout of the unit pixels in a pixel array unit illustrated in FIG. 1, etc.

FIG. 8 is a schematic diagram illustrating an example of a planar layout of transistors included in a readout circuit in the pixel array unit illustrated in FIG. 1, etc.

FIG. 9 is a timing waveform chart illustrating an operation example of the imaging device illustrated in FIG. 1, etc.

FIG. 10 is a diagram illustrating shading characteristics of a general imaging device.

FIG. 11 is a diagram illustrating the shading characteristics of the imaging device illustrated in FIG. 1, etc.

FIG. 12A is a schematic planar diagram illustrating an example of a layout of unit pixels in a pixel array unit of an imaging device according to Modification example 1 of the present disclosure.

FIG. 12B is a schematic planar diagram illustrating another example of the layout of the unit pixels in the pixel array unit of the imaging device according to Modification example 1 of the present disclosure.

FIG. 12C is a schematic planar diagram illustrating another example of the layout of the unit pixels in the pixel array unit of the imaging device according to Modification example 1 of the present disclosure.

FIG. 13 is a schematic cross-sectional view of an example of a configuration of an imaging device according to Modification example 2 of the present disclosure.

FIG. 14 is a schematic cross-sectional view of another example of the configuration of the imaging device according to Modification example 2 of the present disclosure.

FIG. 15 is a schematic cross-sectional view of another example of the configuration of the imaging device according to Modification example 2 of the present disclosure.

FIG. 16 is a schematic cross-sectional view of another example of the configuration of the imaging device according to Modification example 2 of the present disclosure.

FIG. 17 is a schematic cross-sectional view of another example of the configuration of the imaging device according to Modification example 2 of the present disclosure.

FIG. 18 is a schematic cross-sectional view of another example of the configuration of the imaging device according to Modification example 2 of the present disclosure.

FIG. 19 is a block diagram illustrating a configuration example of an electronic apparatus including the imaging device illustrated in FIG. 1, etc.

FIG. 20A is a schematic diagram illustrating an example of an overall configuration of a photodetection system using the imaging device illustrated in FIG. 1, etc.

FIG. 20B is a diagram illustrating an example of a circuit configuration of the photodetection system illustrated in FIG. 20A.

FIG. 21 is an explanatory diagram illustrating an example of use of an imaging device.

FIG. 22 is a block diagram depicting an example of schematic configuration of a vehicle control system.

FIG. 23 is a diagram of assistance in explaining an example of installation positions of an outside-vehicle information detecting section and an imaging section.

### MODES FOR CARRYING OUT THE INVENTION

In the following, a description will be given of one embodiment of the present disclosure in detail with reference to the drawings. The following description relates to one specific example of the present disclosure, and the present disclosure is not limited to the following aspects. In addition, the present disclosure is not limited to those aspects also in terms of the arrangement, dimensions, dimension ratios, or the like, of components illustrated in each of the drawings. It is to be noted that the description will be given in the following order.
1. Embodiment

(An example of an imaging device where in a pixel array unit in which multiple unit pixels each including a first pixel and a second pixel having different sensitivities are arranged in a matrix, the second pixels are each disposed in corresponding one of the unit pixels to allow the second pixels to be equal to each other in distance from the center of the pixel array unit, on the basis of respective positions of the multiple unit pixels in which the respective second pixels are provided)
2. Modification Examples
   2-1. Modification Example 1 (Another example of a layout of the unit pixels in the pixel array unit)
   2-2. Modification Example 2 (Another example of a structure of an element isolator)
3. Application Examples
4. Usage Examples
5. Practical Application Examples

### 1. EMBODIMENT

### [Overall Configuration of Imaging Device]

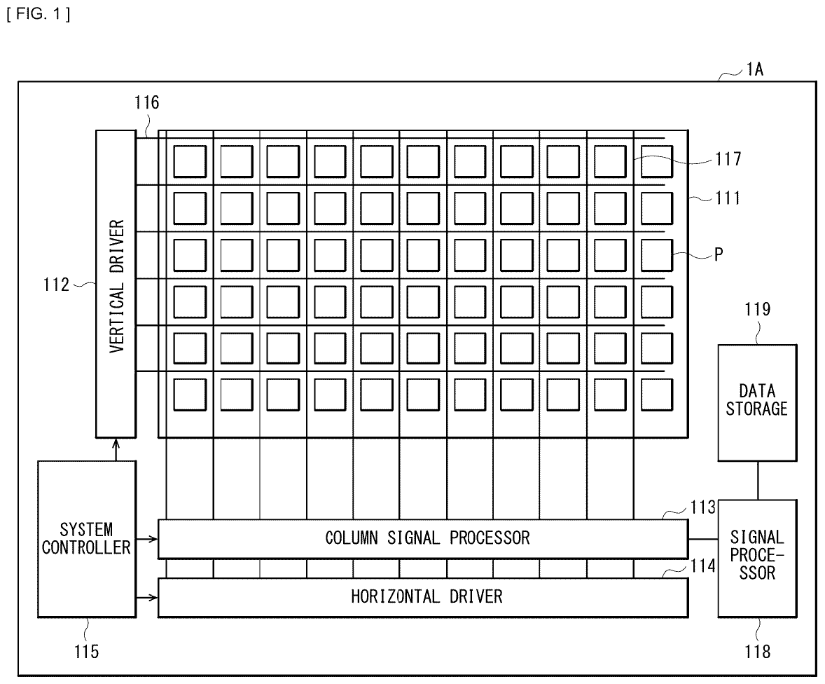

FIG. 1 is a block diagram illustrating a configuration example of functions of an imaging device 1 (imaging device 1A) according to one embodiment of the present disclosure.

The imaging device 1A is, for example, a back-illuminated image sensor of what is called a global shutter method, such as a CMOS (Complementary Metal Oxide Semiconductor) image sensor. The imaging device 1A captures an image by receiving light from a subject, photoelectrically converting the light, and generating an image signal.

The global shutter method is basically a method of performing global exposure in which all pixels start exposure at the same time and all pixels end the exposure at the same time. Here, all pixels mean all of pixels in a portion appearing in an image, and a dummy pixel or the like is excluded. In addition, the global shutter method includes a method of moving through a region to be globally exposed while performing global exposure on multiple rows (several tens of rows, for example), rather than on all pixels at the same time, as long as time difference or image distortion is small enough that it does not become an issue. The global shutter method also includes a method of performing global exposure on pixels in a predetermined region, rather than on all of the pixels in the portion appearing in the image.

The back-illuminated image sensor refers to an image sensor having a configuration in which a photoelectric converter, such as a photodiode, that receives light from a subject and converts the light into an electrical signal is provided between a light receiving surface where the light from the subject enters and a wiring layer where wiring lines for transistors driving respective pixels, or the like, are provided.

The imaging device 1A includes, for example, a pixel array unit 111, a vertical driver 112, a column signal processor 113, a data storage 119, a horizontal driver 114, a system controller 115, and a signal processor 118.

In the imaging device 1A, the pixel array unit 111 is provided on a semiconductor substrate 11 (to be described later). Peripheral circuits including, without limitation, the vertical driver 112, the column signal processor 113, the data storage 119, the vertical driver 114, the system controller 115, and the signal processor 118 are provided on, for example, the semiconductor substrate 11 as with the pixel array unit 111.

The pixel array unit 111 includes multiple unit pixels P each including a photoelectric converter 12 (to be described later) that generates and accumulates charge according to an amount of light entering from the subject. As illustrated in FIG. 1, the unit pixels P are arranged in each of a horizontal direction (row direction) and a vertical direction (column direction). In the pixel array unit 111, a pixel drive line 116 is wired along the row direction for each pixel row including the unit pixels P arranged in one line in the row direction, and a vertical signal line (VSL) 117 is wired along the column direction for each pixel column including the unit pixels P arranged in one line in the column direction.

The vertical driver 112 includes a shift register, an address decoder, etc. By supplying a signal or the like to each of the multiple unit pixels P via multiple pixel drive lines 116, the vertical driver 112 causes all of the multiple unit pixels P in the pixel array unit 111 to be driven simultaneously or causes the unit pixels P to be driven on an pixel row unit basis.

A signal outputted from each of the unit pixels P of the pixel row selected and scanned by the vertical driver 112 is supplied to the column signal processor 113 through each of the VSLs 117. The column signal processor 113 performs, for each of the pixel columns in the pixel array unit 111, predetermined signal processing on the signals outputted through the VSLs 117 from each of the unit pixels in the selected row, and temporarily retains the pixel signals after the signal processing.

Specifically, the column signal processor 113 includes, for example, a shift register, an address decoder, etc., performs noise removal processing, correlated double sampling processing, A/D (Analog/Digital) conversion A/D conversion processing of an analog pixel signal, or the like, and generates digital pixel signals. The column signal processor 113 supplies the generated pixel signals to the signal processor 118.

The horizontal driver 114 includes a shift register, an address decoder, etc., and selects respective unit circuits corresponding to the pixel columns of the column signal processor 113 in sequence. Through the selection and the scanning by the horizontal driver 114, the pixel signals subjected to signal processing for each of the unit circuits in the column signal processor 113 are outputted to the signal processor 118 in sequence.

The system controller 115 includes a timing generator that generates various types of timing signals, etc. The system controller 115 performs drive control of the vertical driver 112, the column signal processor 113, and the horizontal driver 114, on the basis of the timing signals generated by the timing generator.

The signal processor 118 performs signal processing such as arithmetic processing on the pixel signals supplied from the column signal processor 113, while temporarily storing data in the data storage 119 as necessary, and outputs an image signal including each of the pixel signals.

The data storage 119 temporarily stores data necessary for signal processing when the signal processor 118 performs the signal processing.

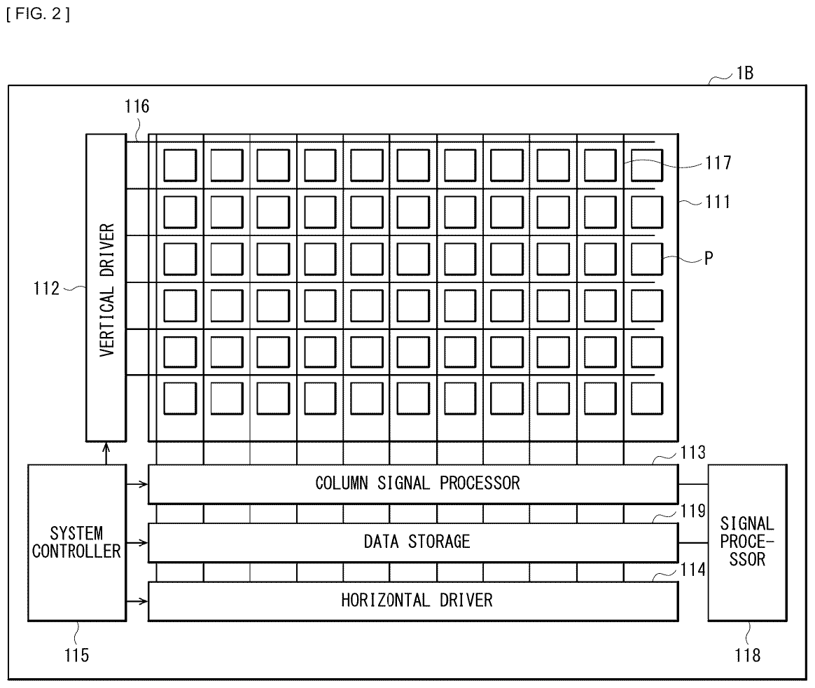

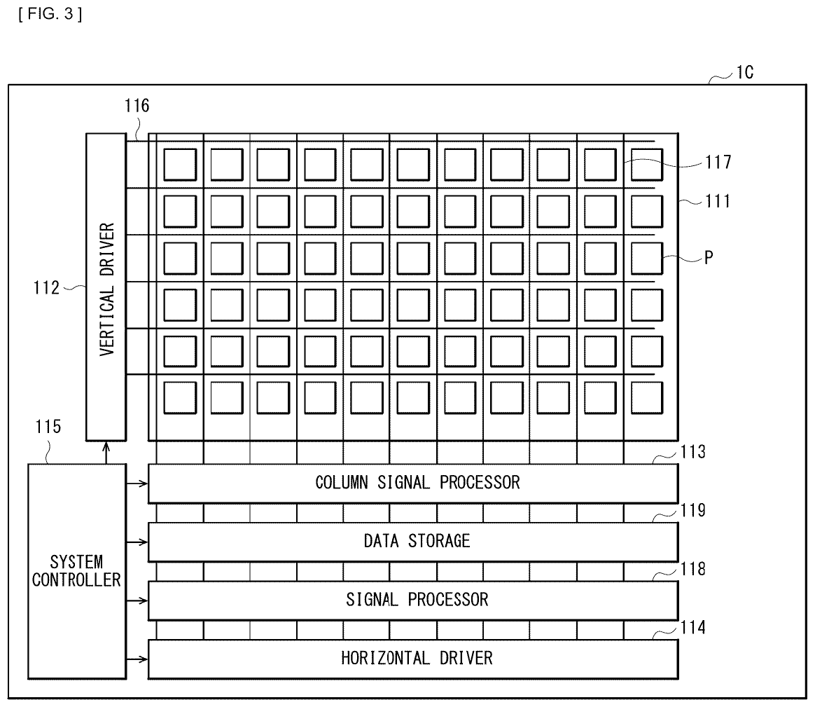

It is to be noted that the imaging device 1 of the present disclosure is not limited to the imaging device 1A illustrated in FIG. 1, and may have, for example, a configuration of an imaging device 1B illustrated in FIG. 2 or an imaging device 1C illustrated in FIG. 3. FIG. 2 is a block diagram illustrating a configuration example of functions of the imaging device 1B as a first modification example of the embodiment of the present disclosure. FIG. 3 is a block diagram illustrating a configuration example of functions of the imaging device C as a second modification example of the embodiment of the present disclosure.

In the imaging device 1B of FIG. 2, the data storage 119 is provided between the column signal processor 113 and the horizontal driver 114, and the pixel signals outputted from the column signal processor 113 are supplied to the signal processor 118 via the data storage 119.

In the imaging device 1C of FIG. 3, the data storage 119 and the signal processor 118 are provided in parallel between the column signal processor 113 and the horizontal driver 114. In the imaging device 1C, the column signal processor 113 performs A/D conversion that converts an analog pixel signal into a digital pixel signal for each column of the pixel array unit 111 or for each multiple columns of the pixel array unit 111.

### [Circuit Configuration of Unit Pixel]

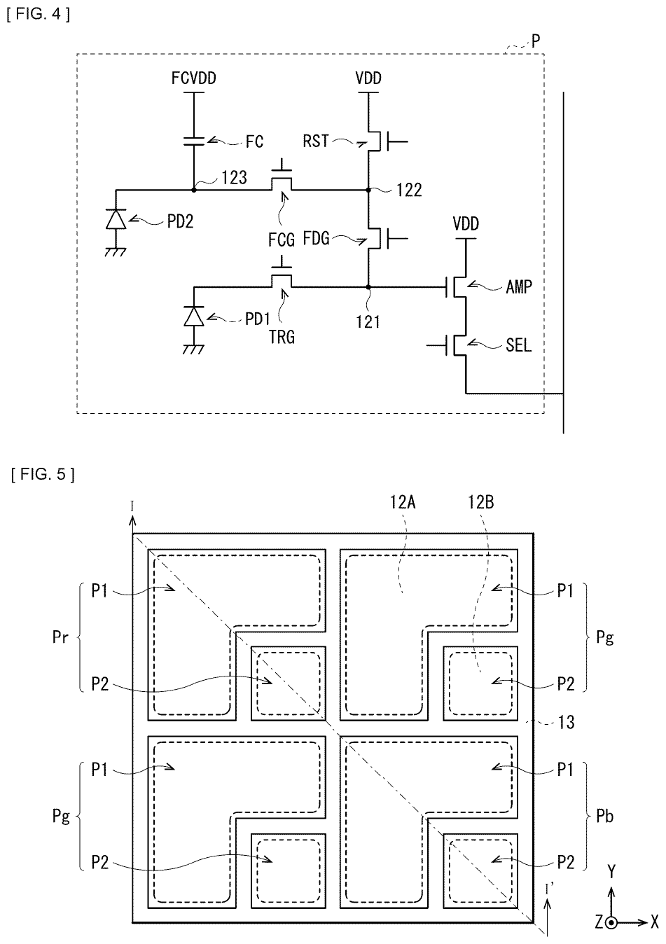

FIG. 4 illustrates an example of a readout circuit of the unit pixel P illustrated in FIG. 1, etc. In the present embodiment, the unit pixel P includes a first pixel (pixel P1) and a second pixel (pixel P2) having different sensitivities. Photoelectric converters 12A and 12B are provided in the pixel P1 and the pixel P2, respectively.

The unit pixel P includes the two photoelectric converters 12A and 12B, a first transfer transistor TRG, a second transfer transistor FDG, a third transfer transistor FCG, a floating diffusion FD 121, a reset transistor RST, an amplification transistor AMP, and a selection transistor SEL. The unit pixel P further includes a charge accumulator FC. The charge accumulator FC is, for example, a MOS capacitor or an MIS capacitor.

The photoelectric converters 12A and 12B are what is called embedded type photodiodes PD1 and PD2 in each of which an n-type impurity region is provided within a p-type impurity region provided in the semiconductor substrate 11. The photoelectric converters 12A and 12B each generate charge according to the amount of received light and accumulate the generated charge up to a certain amount. The photoelectric converter 12A has an anode coupled to a ground voltage line and a cathode coupled to a source of the first transfer transistor TRG. Similarly to the photoelectric converter 12A, the photoelectric converter 12B has an anode coupled to the ground voltage line and a cathode coupled to a source of the third transfer transistor FCG.

The first transfer transistor TRG, the second transfer transistor FRG, and the third transfer transistor FCG are coupled in series between the photoelectric converter 12A and the photoelectric converter 12B. A floating diffusion layer coupled between the first transfer transistor TRG and the second transfer transistor FDG is the FD 121. A floating diffusion layer coupled between the second transfer transistor FDG and a third transfer transistor FDG is a node 122. A floating diffusion layer coupled between the third transfer transistor FDG and the photoelectric converter 12B is a node 123. The charge accumulator FC is coupled to the node 123.

For the unit pixel P, multiple drive lines are disposed as the pixel drive lines 116 illustrated in FIG. 1, etc., for example, for each pixel row. Various types of drive signals STRG, SFDG, SFCG, SRST, and SSEL are supplied from the vertical driver 112 to the unit pixels P via the multiple drive lines. In a case where each of the transistors of the unit pixels P is an NMOS transistor, these drive signals are pulse signals in which a high level (for example, a power supply voltage VDD) state is an active state and a low level state (for example, a negative potential) is an inactive state.

The first transfer transistor TRG is coupled between the photoelectric converter 12A and the FD 121. The drive signal STRG is applied to a gate electrode of the first transfer transistor TRG. When the drive signal STRG becomes active, a transfer gate of the first transfer transistor TRG becomes conductive, and signal charge accumulated in the photoelectric converter 12A is transferred to the FD 121 via the first transfer transistor TRG.

The second transfer transistor FDG is coupled between the FD 121 and the node 122. The drive signal SFDG is applied to a gate electrode of the second transistor FDG. When the drive signal SFDG becomes active and the second transfer transistor FDG becomes conductive, potentials of the FD 121 and the node 122 are combined to be one charge accumulation region.

Charge accumulated in the photoelectric converter 12B is transferred to the charge accumulator FC. The third transfer transistor FCG is coupled between the node 122 and the node 123. The drive signal SFCG is applied to a gate electrode of the third transfer transistor FCG. When the drive signal SFDG and the drive signal SFCG become active and the second transfer transistor FDG and the third transfer transistor FCG become conductive, potentials from the FD 121 to the charge accumulator FC are combined to be one charge accumulation region. In a case where the second transfer transistor FDG and the third transfer transistor FCG are active, potentials from the charge accumulator FC to the FD 121 are combined, and the charge accumulated in the photoelectric converter 12B is transferred to that combined charge accumulation region.

One of two electrodes of the charge accumulator FC is coupled to the node 123, and another of the two electrodes of the charge accumulator FC is coupled to a power supply potential FCVDD, for example.

In addition to the second transistor FDG, the reset transistor RST is also coupled to the node 122.

The reset transistor RST is coupled between the node 122 and a power supply VDD. The drive signal SRST is applied to a gate electrode of the reset transistor RST. When the drive signal SRST becomes active, a reset gate of the reset transistor RST becomes conductive, and the potential of the node 122 is reset to a level of the power supply VDD.

In a case where the drive signal SFDG of the second transfer transistor FDG and the drive signal SFCG of the third transfer transistor FCG are activated when the drive signal SRST is activated, the potentials of the FD 121, the node 122, and the charge accumulator FC whose potentials have been combined are reset to the level of the voltage VDD.

It is to be noted that individually controlling the drive signal SFDG and the drive signal SFCG makes it possible to reset the potentials of the FD 121 and the charge accumulator FC independently of each other to the level of the voltage VDD.

The FD 121 is coupled between the first transfer transistor TRG, a second transfer transistor DG, and the amplification transistor AMP. The FD 121 performs charge-voltage conversion on signal charge transferred by the first transfer transistor TRG and the second transfer transistor DG to convert it into a voltage signal, and outputs the voltage signal to the amplification transistor AMP.

The amplification transistor AMP has a gate electrode coupled to the FD 121 and a drain electrode coupled to the power supply VDD, and serves as an input unit for what is called a source follower circuit that is a readout circuit for voltage signals held by the FD 121. That is, a source electrode of the amplification transistor AMP is coupled to the vertical signal line 117 via the selection transistor SEL, and the amplification transistor AMP thus forms the source follower circuit with a constant current supply coupled to one end of the vertical signal line 117.

The selection transistor SEL is coupled between a source electrode of the amplification transistor AMP and the vertical signal line 117. The drive signal SSEL is applied to a gate electrode of the selection transistor SEL. When this drive signal SSEL becomes active, the selection transistor SEL becomes conductive, and the unit pixel P is in a selected state. As a result, a readout signal (pixel signal) outputted from the amplification transistor AMP is outputted to the vertical signal line 117 via the selection transistor SEL.

In the photoelectric converter 12A, the light receiving area of the photodiode is greater than that of the photoelectric converter 12B. Therefore, in a case where a subject with certain illuminance is photographed for a certain exposure time, charge generated in the photoelectric converter 12A is more than charge generated in the photoelectric converter 12B.

Therefore, when the charge generated in the photoelectric converter 12A and the charge generated in the photoelectric converter 12B are transferred to the FD 121 and are each subjected to the charge-voltage conversion, a voltage change before and after the charge generated in the photoelectric converter 12A is transferred to the FD 121 is greater than a voltage change before and after the charge generated in the photoelectric converter 12B is transferred to the FD 121. Therefore, when the pixel P1 and the pixel P2 are compared with each other, the pixel P1 has a higher sensitivity than the pixel P2.

In contrast, even in a case where light with high illuminance enters and charge beyond a full well capacity of the photoelectric converter 12B is generated, it is possible for the photoelectric converter 12B to accumulate charge generated in excess of the full well capacity in the charge accumulator FC. Therefore, when the charge generated in the photoelectric converter 12B is subjected to the charge-voltage conversion, it is possible to perform the charge-voltage conversion after the charge accumulated in the photoelectric converter 12B and the charge accumulated in the charge accumulator FC are both added.

This makes it possible for the pixel P2 to photograph an image with more gradation than the pixel P1 over a wider illuminance range. In other words, it is possible to photograph an image with a wider dynamic range.

Two images, i.e., an image with a higher sensitivity photographed by using the pixel P1 and an image with a wider dynamic range photographed by using the pixel P2 are, for example, subjected to wide dynamic range image synthesis processing and combined into one image. The wide dynamic range image synthesis processing combines two images into one image and is performed in an image signal processing circuit provided, for example, inside or outside the imaging device 1.

### [Configuration of Unit Pixel]

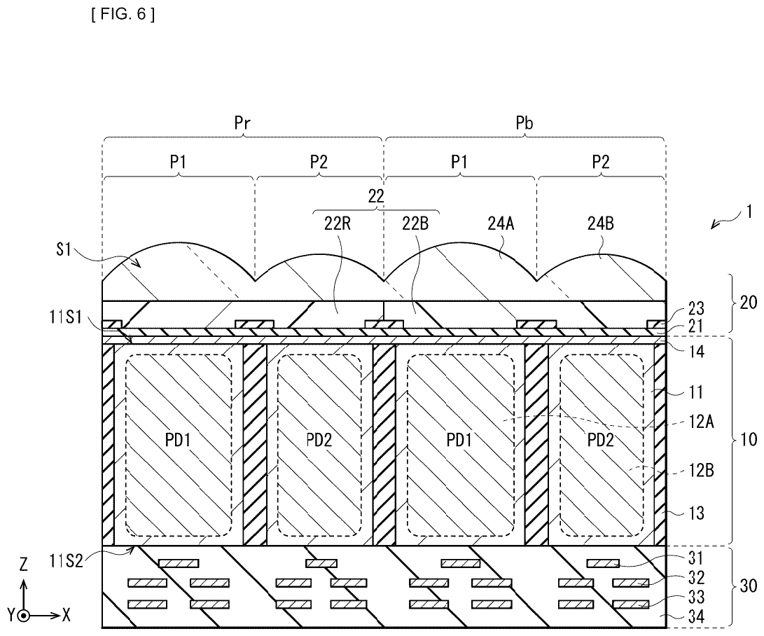

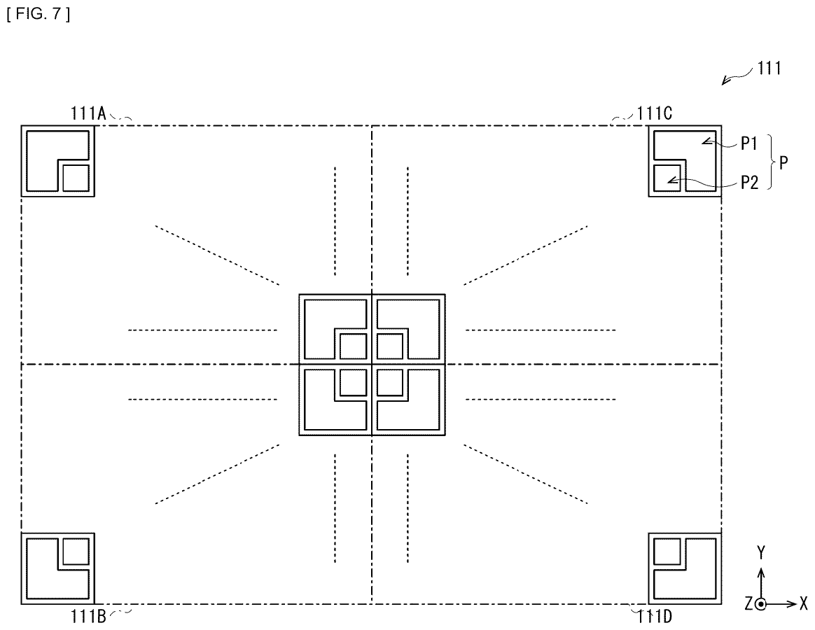

FIG. 5 schematically illustrates an example of a planar configuration of the unit pixel P of the imaging device 1 of the present embodiment. FIG. 6 schematically illustrates an example of a cross-sectional configuration of the imaging device 1 corresponding to a line I-I′ illustrated in FIG. 5.

As described above, the imaging device 1 is, for example, a back-illuminated image sensor. Each of the multiple unit pixels P two-dimensionally disposed in a matrix in the pixel array unit 111 has, for example, a configuration in which a light receiver 10; a light collector 20 provided on light entering side S1 of the light receiver 10; and a multilayer wiring layer 30 provided on side opposite to the light entering side S1 of the light receiver 10 are stacked.

The light receiver 10 includes the semiconductor substrate 11 having a first surface 11S1 and a second surface 11S2 that are opposed to each other, and the multiple photoelectric converters 12A and 12B embedded and formed in the semiconductor substrate 11 and having mutually different light receiving areas. The semiconductor substrate 11 includes a silicon substrate, for example. The photoelectric converters 12A and 12B are each, for example, a PIN (Positive Intrinsic Negative) type photodiode (PD) and each have a pn junction in a predetermined region of the semiconductor substrate 11.

In the present embodiment, the unit pixel P includes the two pixels P1 and P2 having the different sensitivities as described above. Specifically, the pixel P1 converts a larger amount of charge per unit time than the pixel P2, and includes the photoelectric converter 12A that has a larger light receiving area than the photoelectric converter 12B. The pixel P2 converts a smaller amount of charge per unit time than the pixel P1, and includes the photoelectric converter 12B that has a smaller light receiving area than the photoelectric converter 12A.

The light receiver 10 further includes an element isolator 13. The element isolator 13 is provided between the adjacent unit pixels P. In other words, the element isolator 13 is provided around the unit pixels P and is provided in a grid in a pixel section 100A. Furthermore, the element isolator 13 is provided between the pixel P1 and the pixel P2.

The element isolator 13 is adapted to electrically isolate the adjacent unit pixels P from each other and electrically isolate the pixel P1 and the pixel P2 from each other, and extends, for example, from the first surface 11S1 side toward the second surface 11S2 side of the semiconductor substrate 11. The element isolator 13 includes, for example, an impurity injected region.

A fixed charge layer 14 that also serves to prevent reflection on the first surface 11S1 is further provided on the first surface 11S1 of the semiconductor substrate 11. The fixed charge layer 14 may be a film having positive fixed charge or a film having negative fixed charge. Examples of constituent materials of the fixed charge layer 14 include a semiconductor material or a conductive material having a wider bandgap than the bandgap of the semiconductor substrate 11. Specifically, examples include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), aluminum oxynitride (AlOₓN_{y}), and the like. The fixed charge layer 14 may be a single-layer film or a multilayer film including different materials.

The light collector 20 is provided on the light entering side S1 of the light receiver 10, and includes, for example, an insulating layer 21; a color filter 22 that selectively transmits, for example, red light (R), green light (G), or blue light (B) for each unit pixel P; and a light shielding section 23 provided between the unit pixels P of the color filter 22. The light collector 20 further includes multiple on-chip lenses 24A and 24B disposed on an upper surface of the color filter 22 for each of the pixels P1 and P2.

The insulating layer 21 is to reduce deterioration in dark characteristics, and is provided on the fixed charge layer 14, for example. In addition, the insulating layer 21 makes it possible to suppress reflection of light caused by a difference in refractive index between the semiconductor substrate 11 and the color filter 22, by appropriately setting the refractive index of the material and a film thickness. The constituent material of the insulating layer 21 is preferably a material having a lower refractive index than the fixed charge layer 14 and includes, for example, silicon oxide (SiOₓ), silicon nitride (SiNₓ), silicon oxynitride (SiOₓN_{y}), or the like.

The color filter 22 selectively transmits light of a predetermined wavelength. The color filter 22 includes, for example, a color filter 22G that selectively transmits green light (G), a color filter 22R that selectively transmits red light (R), and a color filter 22B that selectively transmits blue light (B). In addition, the color filter 22 may include respective filters that selectively transmit cyan, magenta, and yellow. In the unit pixels P in which the color filters 22R, 22G, and 22B are provided, for example, light of a corresponding color is detected in each of the unit pixels P.

In the color filter 22, for example, two color filters 22G selectively transmitting green light (G) are diagonally disposed with respect to the four unit pixels P arranged in two rows and two columns, and one color filter 22R selectively transmitting red light (R) and one color filter 22B selectively transmitting blue light (B) are disposed on an orthogonal diagonal line. In the unit pixels P in which the respective color filters 22R, 22G, and 22B are provided, for example, the respective photoelectric converters 12 detect light of corresponding colors. That is, in the pixel array unit 111, unit pixels Pr, Pg, and Pb that detect red light (R), green light (G), and blue light (B), respectively, are arranged in a Bayer pattern.

It is possible to form the color filter 22 using a pigment or a dye, for example. The color filter 22 may have a film thickness that differs between colors, in consideration of color reproducibility based on optical spectrum or the sensor sensitivity. It is to be noted that in a monochrome pixel, it is possible to regard a layer including a transparent material as the color filter 22. In an infrared pixel, it is possible to regard a layer including a material that selectively transmits infrared rays as the color filter 22.

The light shielding section 23 is adapted to prevent a leakage into adjacent unit pixels P of light that is obliquely incident on the color filter 22, and is provided between the adjacent unit pixels P and between the adjacent pixels P1 and P2. In other words, the light shielding section 23 is provided to have an approximately same layout as, for example, the element isolator 13 in a planar view.

Examples of a material included in the light shielding section 23 include a material having a light shielding property. Specifically, the examples include tungsten (W), silver (Ag), copper (Cu), titanium (Ti), aluminum (Al), and alloys thereof. In addition, other examples include a metal compound such as TiN. The light shielding section 23 may be provided as, for example, a single-layer film or a multilayer film. In a case where the light shielding section 23 is provided as the multilayer film, it is possible to provide, as an underlayer, a layer including Ti, tantalum (Ta), W, cobalt (Co), molybdenum (Mo), an alloy thereof, a nitride thereof, an oxide thereof, or a carbide thereof in order to enhance adhesiveness to the insulating layer 21.

The light shielding section 23 may also serve to shield light for the unit pixels P that determine an optical black level. The light shielding section 23 may also serve to shield light for suppressing production of noise in a peripheral circuit provided in a surrounding region of the pixel array unit 111. It is preferable that the light shielding section 23 be grounded so as not to be destroyed by a plasma damage due to accumulated charge during treatment.

As illustrated in FIG. 6, for example, the multiple on-chip lenses 24A and 24B are provided for the pixels P1 and P2, respectively, and are adapted to converge light entering from above the on-chip lenses 24A and 24B onto the photoelectric converters 12A and 12B. The multiple on-chip lenses 24A and 24B are, for example, provided without any gap therebetween. For example, in a planar view, the element isolator 13 approximately coincides with a boundary between the multiple on-chip lenses 24A and 24B. The multiple on-chip lenses 24A and 24B each include an inorganic material such as silicon oxide (SiOₓ) or silicon nitride (SiNₓ), for example. In addition to this, the multiple on-chip lenses 24A and 24B may include an organic material with a high refractive index such as an episulphide-based resin, a thietane compound, or a resin of the thietane compound.

The multilayer wiring layer 30 is provided on the side opposite to the light entering side S1 of the light receiver 10, specifically, on side of the second surface 11S2 of the semiconductor substrate 11. The multilayer wiring layer 30 has, for example, a configuration in which multiple wiring layers 31, 32, and 33 are stacked with an inter-layer insulating layer 34 interposed therebetween. In the multilayer wiring layer 30, the vertical driver 112, the column signal processor 113, the horizontal driver 114, the system controller 115, the signal processor 118, and the data storage 119, etc., are provided, in addition to the readout circuit described above.

The wiring layers 31, 32, and 33 include, for example, aluminum (Al), copper (Cu), tungsten (W), or the like. In addition to this, the wiring layers 31, 32, and 33 may include polysilicon (Poly-Si).

The inter-layer insulating layer 34 includes, for example, a single-layer film including one of silicon oxide (SiOₓ), TEOS, silicon nitride (SiNₓ), silicon oxynitride (SiOₓN_{y}), etc., or a multilayer film including two or more thereof.

### [Planar Layout of Unit Pixels]

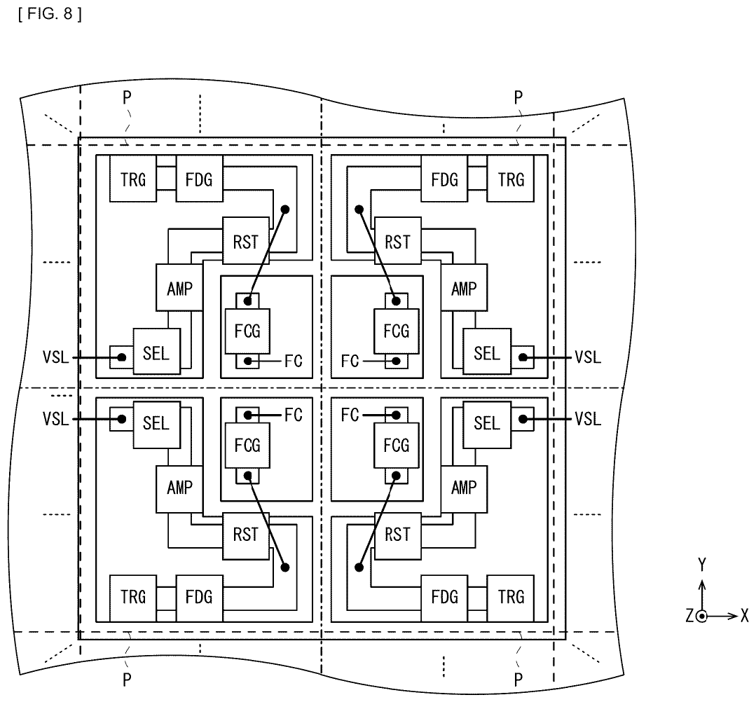

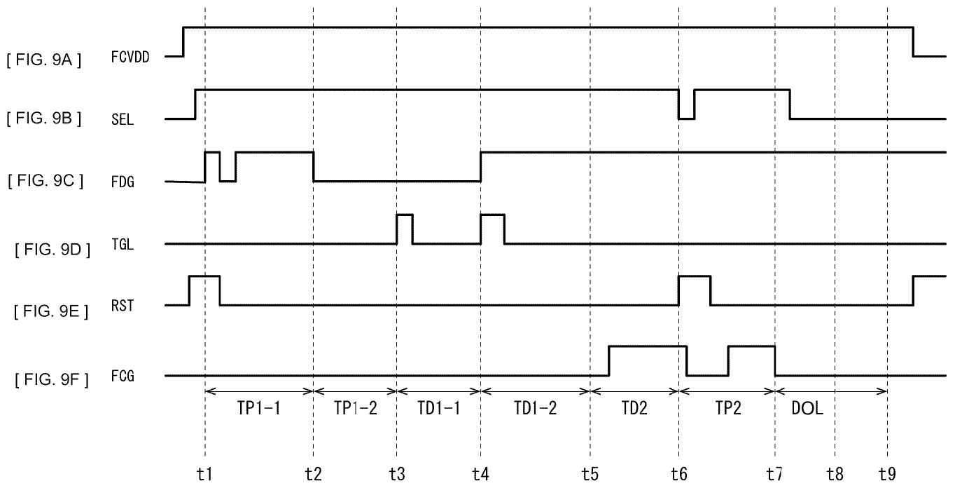

FIG. 7 schematically illustrates an example of a planar layout of the unit pixels P in the pixel array unit 111. FIG. 8 schematically illustrates an example of a planar layout of the transistors each included in the readout circuit in the pixel array unit 111.

In the pixel array unit 111, the multiple unit pixels P are arranged in a matrix. Each of the multiple unit pixels P includes the pixel P1, and the P2 converting a smaller amount of charge per unit time than the pixel P1. In the present embodiment, the pixels P2 each provided in corresponding one of the multiple unit pixels P are disposed to allow the pixels P2 to be equal to each other in distance from the center of the pixel array unit 111, on the basis of the respective positions, in the pixel array unit 111, of the multiple unit pixels P in which the respective pixels P2 are provided, in a planar view.

For example, the unit pixels P and the pixels P2 each have an approximately rectangular shape, as illustrated in FIG. 5. The pixel P2 corresponds to, for example, one section where the unit pixel P is equally divided into four sections, in a planar view, and is provided, being offset to any of four corners of the unit pixel P having the approximately rectangular shape, as illustrated in FIG. 5. The remaining three sections of the four sections are the pixel P1.

As illustrated in FIG. 7, for example, the pixel array unit 111 also has an approximately rectangular shape. The pixels P2 are each provided in corresponding one of the multiple unit pixels P arranged in a matrix in the pixel array unit 111, and provided, being offset to any of the four corners of the unit pixel P having the approximately rectangular shape. As illustrated in FIG. 7, for example, such pixels P2 are so disposed as to face each other at the center of the pixel array unit 111. That is, in the unit pixel P disposed at the upper left at the center of the pixel array unit 111, the pixel P2 is disposed at the lower right. In the unit pixel disposed at the lower left at the center of the pixel array unit 111, the pixel P2 is disposed at the upper right. In the unit pixel disposed at the upper right at the center of the pixel array unit 111, the pixel P2 is disposed at the lower left. In the unit pixel P disposed at the lower right at the center of the pixel array unit 111, the pixel P2 is disposed at the upper left.

In the pixel array unit 111 as a whole, in a planar view, the pixels P2 each disposed in corresponding one of the multiple unit pixels P arranged in a matrix in the pixel array unit 111 are point-symmetrically disposed about the center of the pixel array unit 111, as illustrated in FIG. 7, for example. This allows the pixels P1 and P2 each provided in corresponding one of the multiple unit pixels P to be equal to each other in distance from the center of the pixel array unit 111, in a planar view. Therefore, the unit pixels P disposed at equal distances from the center of the pixel array unit 111 have same output.

Specifically, in a planar view, in a case where the pixel array unit 111 is divided at the center into, for example, approximately equal four regions (a first region 111A, a second region 111B, a third region 111C, and a fourth region 111D) that are orthogonal to the X-axis direction and the Y-axis direction, in the first region 111A including the above-described unit pixel P disposed at the upper left at the center of the pixel array unit 111, the multiple unit pixels P in which the respective pixels P2 are disposed at the lower right of the similar unit pixels P are arranged in a matrix. In the second region 111B including the above-described unit pixel P disposed at the lower left at the center of the pixel array unit 111, the multiple unit pixels P in which the respective pixels P2 are disposed at the upper right of the similar unit pixels P are arranged in a matrix. In the first region 111A including the unit pixel P disposed at the upper right at the center of the pixel array unit 111, the multiple unit pixels P in which the respective pixels P2 are disposed at the lower left of the similar unit pixels P are arranged in a matrix. In the second region 111B including the above-described unit pixel P disposed at the lower right at the center of the pixel array unit 111, the multiple unit pixels P in which the respective pixels P2 are disposed at the upper left of the similar unit pixels P are arranged in a matrix. In other words, the pixels P2 each disposed in corresponding one of the multiple unit pixels P in the first region 111A, the second region 111B, the third region 111C, and the fourth region 111D are disposed line-symmetrically about the X-axis direction and the Y-axis direction.

Furthermore, in the imaging device 1 of the present embodiment, similarly to the pixels P2 described above, the multiple transistors (the first transfer transistors TRG, the second transfer transistors FDG, the third transfer transistors FCG, the floating diffusions FD 121, the reset transistors RST, the amplification transistors AMP, and the selection transistors SEL) forming the readout circuits provided in the respective unit pixels P in the first region 111A, the second region 111B, the third region 111C, and the fourth region 111D may be disposed line-symmetrically about the X-axis direction and the Y-axis direction, as illustrated in FIG. 8, for example.

### [Readout Operation of Imaging Device]

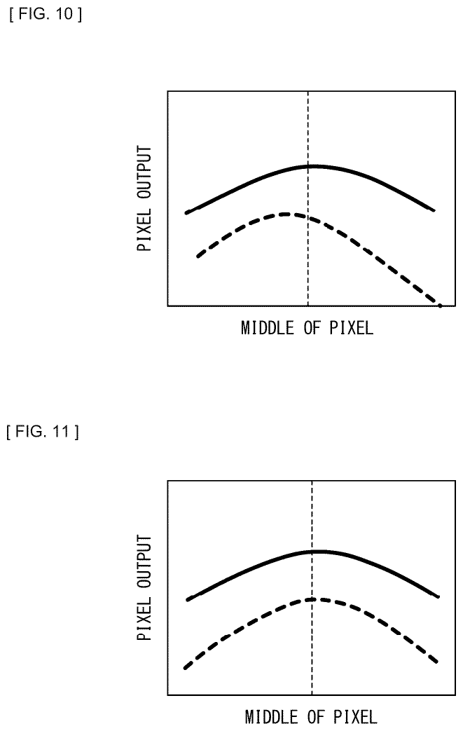

FIG. 9 illustrates an example of a readout operation in the imaging device 1 illustrated in FIG. 1, etc. (A) represents a waveform of the power supply potential FCVDD. (B) represents a potential at a gate of the selection transistor SEL. (C) represents a potential at a gate of the second transfer transistor FDG. (D) represents a potential at a gate of the first transfer transistor TRG. (E) represents a potential at a gate of the rest transistor RST. (F) represents a potential at a gate of the third transfer transistor.

In the unit pixel P, in a P-phase (Pre-charge phase) period TP after a voltage of the FD 121 is reset by the reset transistor RST being turned on, a voltage based on the voltage of the FD 121 at that time is outputted as a reset voltage (reset signal). In addition, in the unit pixel P, in a D-phase (Data phase) period TD after the charge is transferred from the photoelectric converters 12A to 12B to the FD 121 by the first transfer transistor TRG being turned on, a voltage based on the voltage of the FD 121 at that time is outputted as a pixel voltage (pixel signal). In the pixel P1 of the present embodiment, the wide dynamic range is achieved by changing the conversion efficiency between the P-phase and the D-phase and reading out each of the reset signal and the pixel signal twice.

First, a horizontal period H starts. As a result, the vertical driver 112 changes the potential of the power supply potential FCVDD from the low level to the high level (FIG. 9(A)). This turns on the selection transistor SEL in the unit pixel P, coupling the unit pixel P to the vertical signal line 117. In addition, the vertical driver 112 changes the potential of the gate of the reset transistor RST from the low level to the high level (FIG. 9(E)). Furthermore, at timing t1, the vertical driver 112 changes the potential of the gate of the second transistor FDG from the low level to the high level (FIG. 9(C)). As a result, in the unit pixel P, the reset transistor RST and the second transfer transistor FDG are turned on, which sets the voltage of the FD 121 to the power supply voltage VDD (reset operation). Further, the unit pixel P outputs a voltage corresponding to the voltage of the FD 121 at this time.

### [Low Conversion Efficiency P-Phase Period TP1-1 of Pixel P1]

Further, at a timing when a predetermined period of time has elapsed from the timing t1, the vertical driver 112 changes the potential of the gate of the reset transistor RST from the high level to the low level (FIG. 9(E)). At the same time, the vertical driver 112 changes the potential of the gate of the second transistor FDG from the high level to the low level (FIG. 9(C)). In the unit pixel P, this turns off the reset transistor RST and the second transfer transistor FDG, and the reset operation ends.

Furthermore, at the timing when a predetermined period of time has elapsed from the timing t1, the vertical driver 112 changes the potential of the gate of the second transfer transistor FDG from the low level to the high level (FIG. 9(C)). In the unit pixel P, this turns on the second transfer transistor FDG.

### [High Conversion Efficiency P-Phase Period TP1-2 of Pixel P1]

Thereafter, at timing t2, the vertical driver 112 changes the potential of the gate of the second transfer transistor FDG from the high level to the low level. In the unit pixel P, this turns off the second transfer transistor FDG.

### [High Conversion Efficiency D-Phase Period TD1-2 of Pixel P1]

Thereafter, at timing t3, the vertical driver 112 changes the potential of the gate of the first transfer transistor TRG from the low level to the high level as the P-phase period TP1 of the pixel P1 ends. In the unit pixel P, this turns on the first transfer transistor TRG. Thereafter, at a timing when a predetermined period of time has elapsed from the timing t3, the vertical driver 112 changes the potential of the gate of the first transfer transistor TRG from the high level to the low level (FIG. 9(D)). This turns off the first transfer transistor.

### [Low Conversion Efficiency D-Phase Period TD1-1 of Pixel P1]

Thereafter, at timing t4, the vertical driver 112 changes the potential of the gate of the second transfer transistor FDG from the low level to the high level. In the unit pixel P, this turns on the second transfer transistor FDG (FIG. 9(C)). At the same time, the vertical driver 112 changes the gate of the first transfer transistor TRG from the low level to the high level. In the unit pixel P, this turns on the first transfer transistor TRG. Further, at a timing when a predetermined period of time has elapsed from the timing t4, the vertical driver 112 changes the potential of the gate of the first transistor TRG from the high level to the low level (FIG. 9(D)). This turns off the first transfer transistor.

### [D-Phase Period TD2 of Pixel P2]

Thereafter, at timing t5, the vertical driver 112 changes the potential of the gate of the third transfer transistor FCG from the low level to the high level (FIG. 9(F)). This turns on the third transfer transistor FDG.

### [P-Phase Period TP2 of Pixel P2]

Thereafter, at timing t6, the vertical driver 112 changes the potential of the gate of the selection transistor SEL from the high level to the low level as the D-phase period TD1 of the pixels P1 and P2 ends (FIG. 9(B)). This turns off the selection transistor SEL. At the same time, the vertical driver 112 changes the potential of the gate of the reset transistor RST from the low level to the high level (FIG. 9(E)), and changes the potential of the gate of the third transfer transistor FCG from the high level to the low level (FIG. 9(F)). This turns on the reset transistor RST and turns off the third transfer transistor FCG.

Thereafter, at a timing when a predetermined period of time has elapsed from the timing t6, the vertical driver 112 changes the potential of the gate of the selection transistor SEL from the low level to the high level (FIG. 9(B)). This turns on the selection transistor. Furthermore, at a timing when a predetermined period of time has elapsed from the timing t6, the vertical driver 112 changes the potential of the gate of the reset transistor RST from the high level to the low level (FIG. 9(E)), and changes the potential of the gate of the third transfer transistor FCG from the low level to the high level (FIG. 9(F)). This turns off the reset transistor RST and turns on the third transfer transistor FCG.

### [DOL (Digital Overlap) Period]

Thereafter, at timing t7, the vertical driver 112 changes the potential of the gate of the third transfer transistor FCG from the high level to the low level as the P-phase period TP2 of the pixel P2 ends (FIG. 9(F)). This turns off the third transfer transistor FCG. Furthermore, at a timing when a predetermined period of time has elapsed from the timing t7, the vertical driver 112 changes the potential of the gate of the selection transistor SEL from the high level to the low level (FIG. 9(B)). This turns off the selection transistor. Further, in a period from the timing t7 to a timing t9, an accumulation period is changed and readout is performed.

### [Workings and Effects]

The imaging device 1 of the present embodiment includes the pixel array unit 111 in which the multiple unit pixels P are arranged in a matrix. The multiple unit pixels P each include the pixel P1 and the pixel P2. The pixel P2 converts a smaller amount of charge per unit time than the pixel P1. The pixels P2 that are each provided in corresponding one of the multiple unit pixels P are each disposed in corresponding one of the unit pixels P to allow the pixels P2 to be equal to each other in distance from the center of the pixel array unit 111, on the basis of the respective positions, in the pixel array unit 111, of the multiple unit pixels P in which the respective pixels P2 are provided, in a planar view. This reduces a difference in output between the unit pixels P disposed at equal distances from the center of the pixel array unit 111. In the following, this will be described.

As a solid-state imaging device, a CMOS-type solid-state imaging device (CMOS image sensor) has been known, and it is possible to manufacture the CMOS-type solid-state imaging device with processes similar to those of a CMOS integrated circuit. In the CMOS image sensor, a miniaturization technique associated with the CMOS processes makes it possible to easily produce an active-type structure with an amplification function for each pixel. In addition, there is another characteristic that it is possible to integrate a peripheral circuit part such as a signal processing circuit on the same chip (substrate) as the pixel array unit. The peripheral circuit part processes a signal outputted from each pixel of the pixel array unit. Accordingly, more research and development are carried out on the CMOS image sensor.

Incidentally, as described above, regarding the CMOS image sensor, the technique is proposed that expands the dynamic range by providing, in the unit pixel, two types of photoelectric converters (a large pixel and a small pixel) that differ in the amount of charge converted per unit time, and performing signal processing using the difference in sensitivity. As such, in the CMOS image sensor provided with the large pixel and the small pixel in the unit pixel, for example, the large pixel is disposed in alignment with the center of a chip, and the small pixel is disposed being offset from the center of the chip.

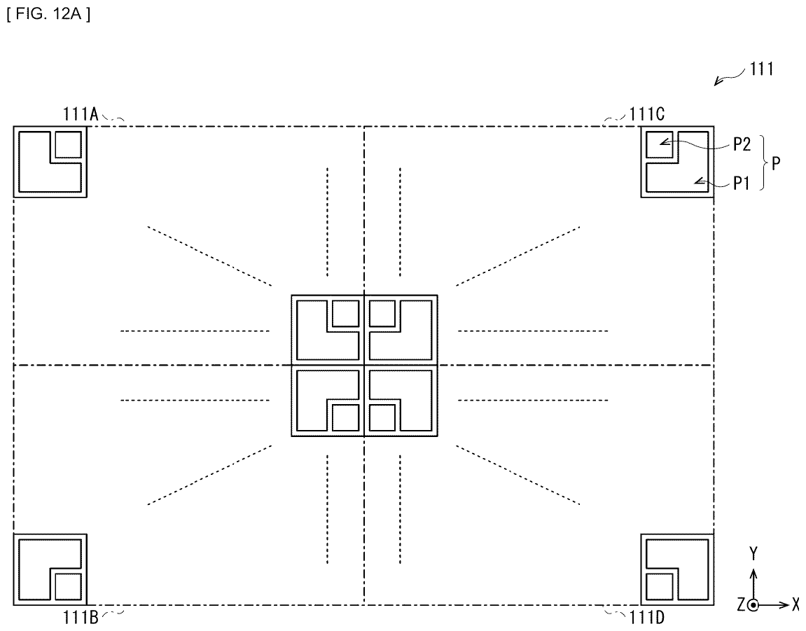

Usually, in a case where pixels are disposed with respect to the center of the chip, output at the center of the chip is high, and the output decreases as the pixels are located away from the center of the chip. In a case where the pixels are disposed at equal distances from the center, outputs of the pixels are equal. However, in a case where the pixels are disposed being misaligned from the center of the chip, as illustrated in FIG. 10, there is an issue that a difference is generated in the pixel outputs even if the pixels are disposed at equal distances from the center, and that the image quality is degraded.

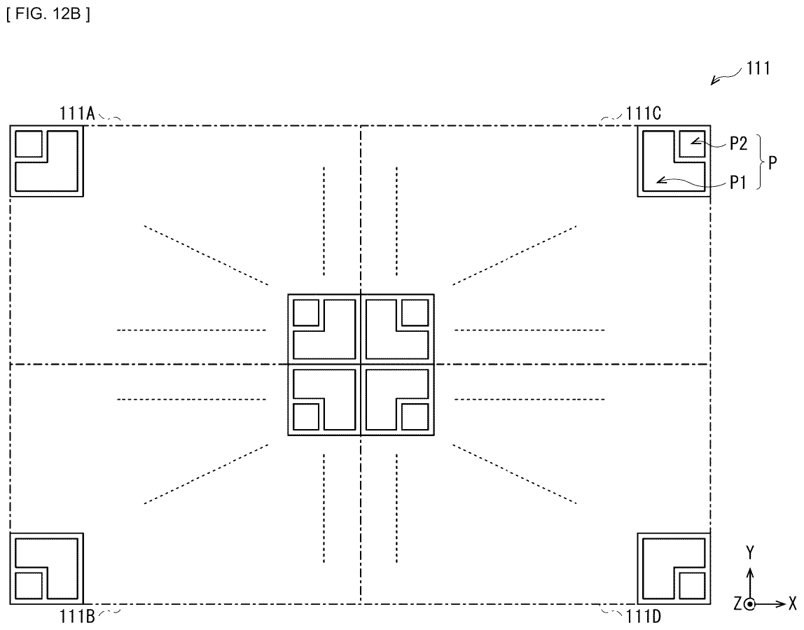

In contrast to this, in the present embodiment, in the pixel array unit 111, the multiple unit pixels P each including the pixel P1 and the pixel P2 are arranged in a matrix. The pixel P2 converts the smaller amount of charge per unit time than the pixel P1. In the pixel array unit 111, the pixels P2 are each disposed in corresponding one of the unit pixels P to allow the pixels P2 to be equal to each other in distance from the center of the pixel array unit 111, in a planar view. Consequently, the outputs of the unit pixels P disposed at equal distances from the center of the pixel array unit 111 become approximately the same, as illustrated in FIG. 11.

As described above, in the imaging device 1 of the present embodiment, it is possible to obtain uniform shading characteristics. Therefore, it becomes possible to improve image quality.

Next, a description will be given of Modification examples 1 and 2 of the present disclosure. In the following, the same reference numerals are given to components similar to those in the above-described embodiment, and a description of the components will be omitted appropriately.

### 2. MODIFICATION EXAMPLES

### 2-1. Modification Example 1

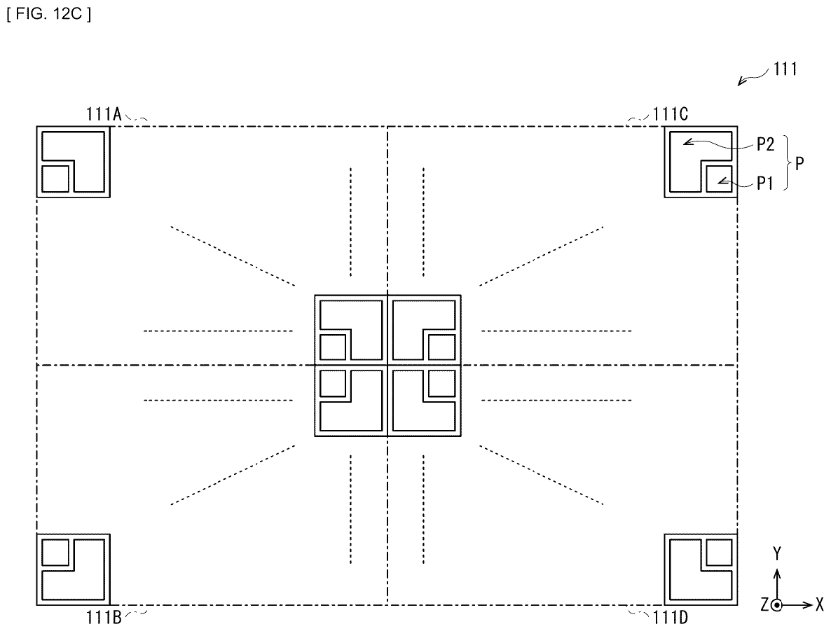

FIG. 12A to FIG. 12C schematically illustrate other examples of the planar layout of the unit pixels P described in the embodiment above. Although in the embodiment described above, the example has been illustrated in which, regarding the pixel array unit 111, the multiple unit pixels P, and the multiple pixels P2 each of which has the approximately rectangular shape, the multiple pixels P2 are disposed to face each other with the respect to the center of the pixel array unit 111, the present disclosure is not limited to this.

It is sufficient that, in a planar view, the multiple pixels P2 are disposed to be equal to each other in distance from the center of the pixel array unit 111, on the basis of the respective positions, in the pixel array unit 111, of the multiple unit pixels P in which the multiple pixels P2 are provided. For example, the multiple pixels P2 may be laid out as described below.

As illustrated in FIG. 12A, for example, in a planar view, in the unit pixel P disposed at the upper left at the center of the pixel array unit 111 and in the first region 111A including this, the pixel P2 is disposed at the upper right. In the unit pixel P disposed at the lower left at the center of the pixel array unit 111 and in the second region 111B including this, the pixel P2 is disposed at the lower right. In the unit pixel P disposed at the upper right at the center of the pixel array unit 111 and in the third region 111C including this, the pixel P2 is disposed at the upper left. In the unit pixel P disposed at the lower right at the center of the pixel array unit 111 and in the fourth region 111D including this, the pixel P2 is disposed at the lower left.

As illustrated in FIG. 12B, for example, in a planar view, in the unit pixel P disposed at the upper left at the center of the pixel array unit 111 and in the first region 111A including this, the pixel P2 is disposed at the upper left. In the unit pixel P disposed at the lower left at the center of the pixel array unit 111 and in the second region 111B including this, the pixel P2 is disposed at the lower left. In the unit pixel P disposed at the upper right at the center of the pixel array unit 111 and in the third region 111C including this, the pixel P2 is disposed at the upper right. In the unit pixel P disposed at the lower right at the center of the pixel array unit 111 and in the fourth region 111D including this, the pixel P2 is disposed at the lower right.

As illustrated in FIG. 12C, for example, in a planar view, in the unit pixel P disposed at the upper left at the center of the pixel array unit 111 and in the first region 111A including this, the pixel P2 is disposed at the lower left. In the unit pixel P disposed at the lower left at the center of the pixel array unit 111 and in the second region 111B including this, the pixel P2 is disposed at the upper left. In the unit pixel P disposed at the upper right at the center of the pixel array unit 111 and in the third region 111C including this, the pixel P2 is disposed at the lower right. In the unit pixel P disposed at the lower right at the center of the pixel array unit 111 and in the fourth region 111D including this, the pixel P2 is disposed at the upper right.

### 2-2. Modification Example 2

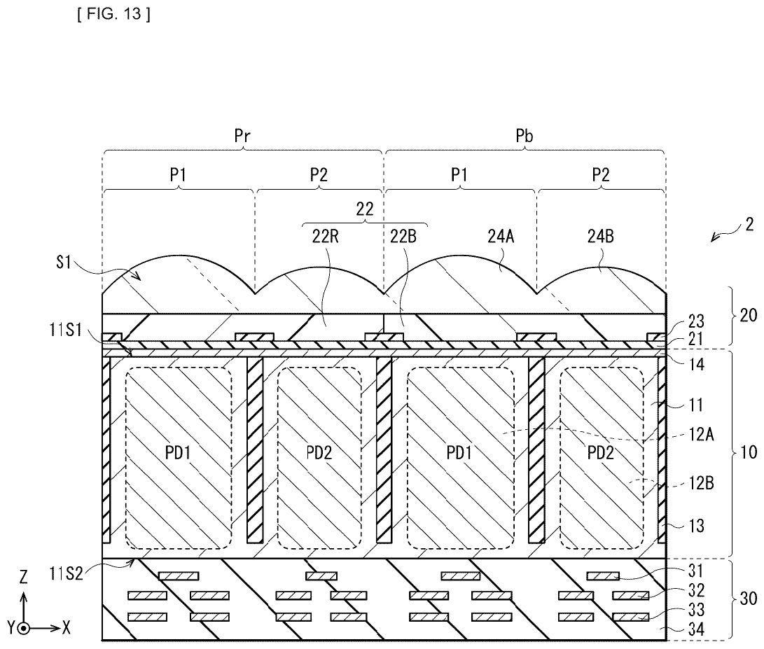

FIG. 13 schematically illustrates an example of a cross-sectional configuration of an imaging device (imaging device 2) according to Modification example 2 of the present disclosure. The imaging device 2 is, for example, what is called a back-illuminated image sensor of the global shutter method such as a CMOS image sensor. The imaging device 2 captures an image by receiving light from a subject, photoelectrically converting the light, and generating an image signal.

In the embodiment described above, although an example is illustrated in which the element isolator 13 includes the impurity injected region, this is non-limiting. As illustrated in FIG. 13, for example, the element isolator 13 may have an RDTI (Rear Deep Trench Isolation) structure in which a groove is provided that extends from the first surface 11S1 side to the second surface 11S2 side of the semiconductor substrate 11, and, for example, an oxide film is embedded in that groove.

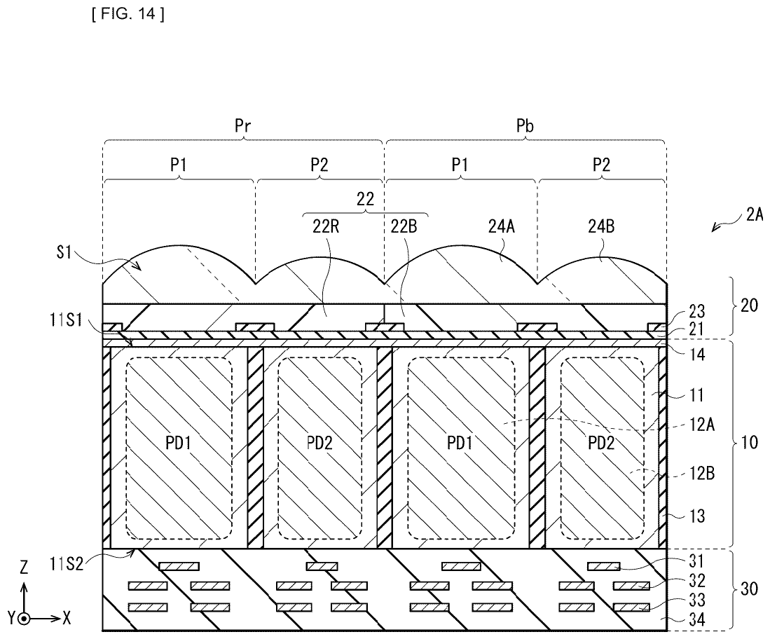

In addition to this, like an imaging device 2A illustrated in FIG. 14, for example, the element isolator 13 may have an FFTI (Front Full Trench Isolation) structure in which, for example, an oxide film is embedded in a groove that passes through from the first surface 11S1 to the second surface 11S2 of the semiconductor substrate 11. In addition to the oxide film, in addition to the oxide film, polysilicon or tungsten may be embedded in the groove.

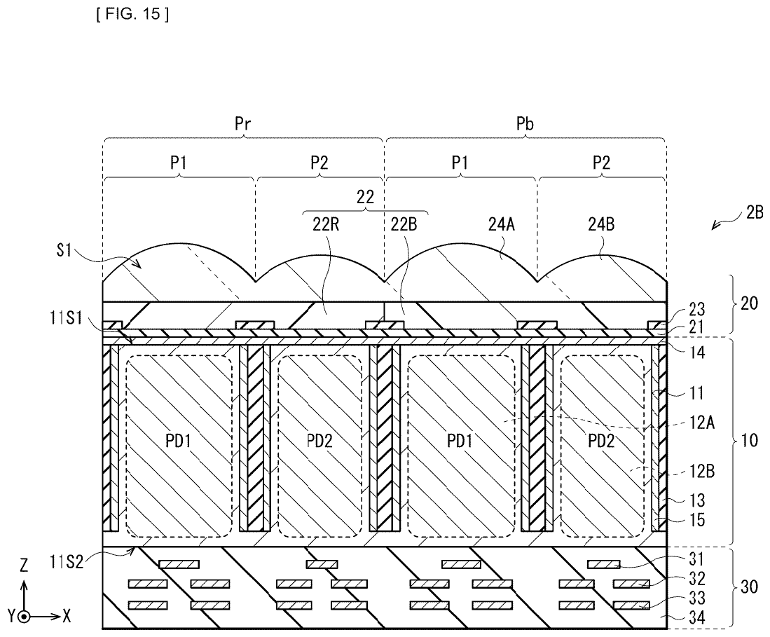

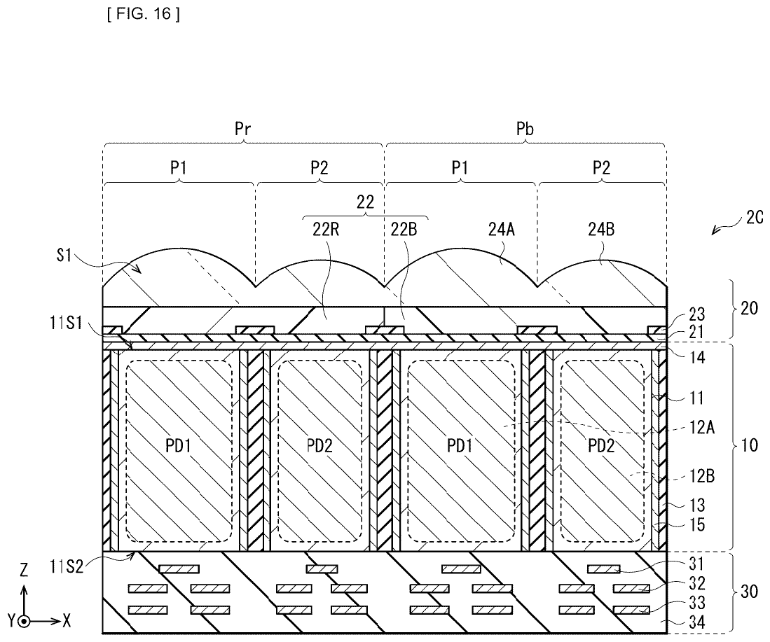

In addition, on a side wall of the element isolator 13 having any of the trench structures illustrated in FIG. 13 and FIG. 14 may be provided with a P-type or an N-type solid-phase diffusion region 15, for example, as in imaging devices 2C and 2D illustrated in FIG. 15 and FIG. 16.

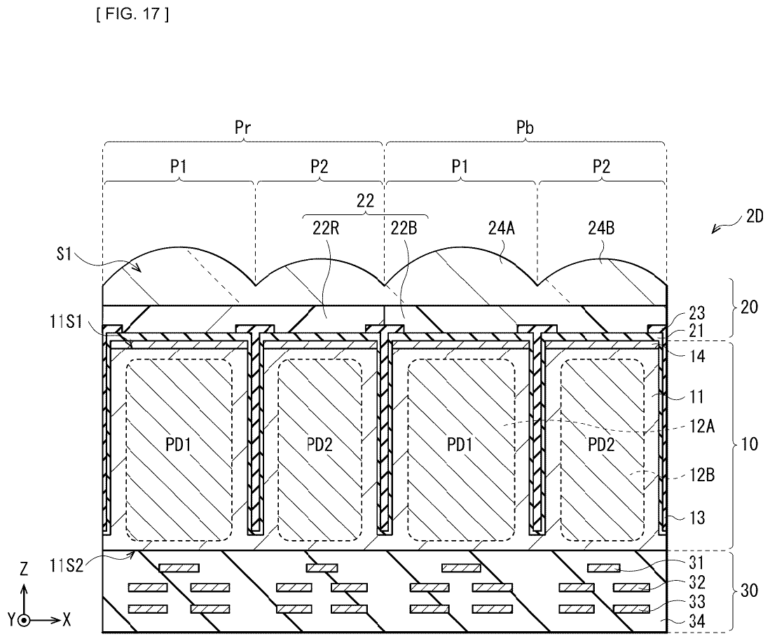

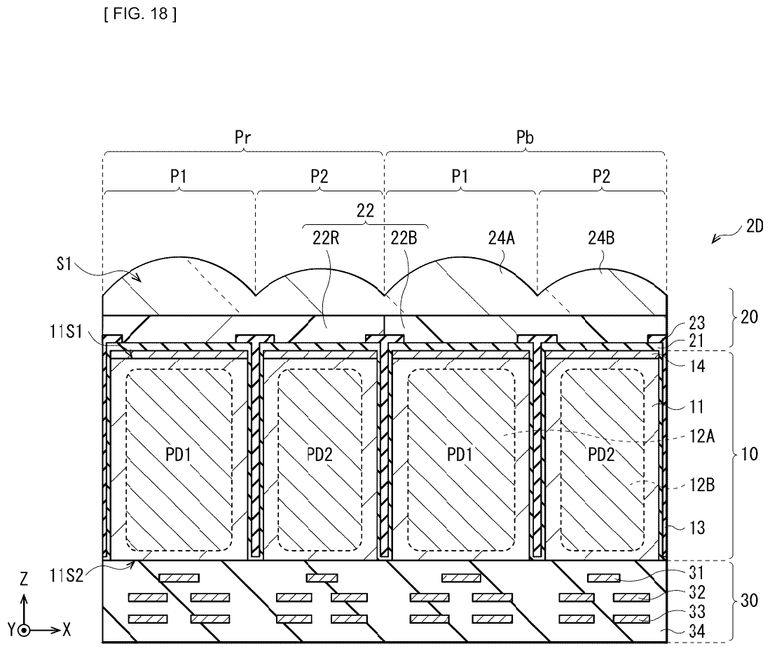

Furthermore, as in imaging devices 2E and 2F illustrated in FIG. 17 and FIG. 18, for example, the light shielding section 23 may be extended in the element isolator having any of the trench structures illustrated in FIG. 13 and FIG. 14. This makes it possible to electrically and optically isolate the unit pixels P from each other, and the pixel P1 and the pixel P2 from each other.

### Other Modification Examples

Moreover, these modification examples may be combined with each other.

### 3. APPLICATION EXAMPLES

### Application Example 1

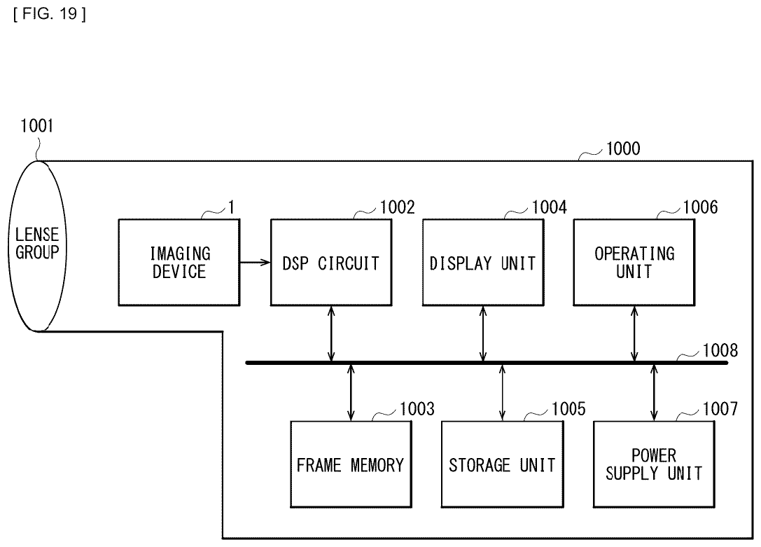

It is possible to apply the imaging device 1 or the like described above to, for example, any type of electronic apparatus with an imaging capability, such as a camera system including a digital still camera and a video camera, or a mobile phone having the imaging capability. FIG. 19 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operating unit 1006, and a power supply unit 1007 that are mutually coupled with each other via a bus line 1008.

The lens group 1001 captures incident light (image light) from a subject and forms an image on an imaging surface of the imaging device 1. The imaging device 1 converts, into an electrical signal, an amount of light of the incident light imaged on the imaging surface by the lens group 1001, and supplies the electrical signal to the DSP circuit 1002 as a pixel signal.

The DSP circuit 1002 is a signal processing circuit that processes a signal supplied from the imaging device 1. The DSP circuit 1002 outputs image data that is obtained by processing the signal from the imaging device 1. The frame memory 1003 temporarily retains the image data processed by the DSP circuit 1002 on a frame unit basis.

The display unit 1004 includes, for example, a panel display such as a liquid crystal panel or an organic EL (Electro Luminescence) panel and records image data of moving images or still images captured by the imaging device 1 in a recording medium such as a semiconductor memory or a hard disk.

The operating unit 1006 outputs operation signals related to various types of functions possessed by the electronic apparatus 1000, in accordance with operations by a user. The power supply unit 1007 appropriately supplies various power supplies that serve as operating power supplies for the DSP circuit 1002, the frame memory 1003, the display unit 1004, the recording unit 1005, and the operating unit 1006, to these supply targets.

### Application Example 2

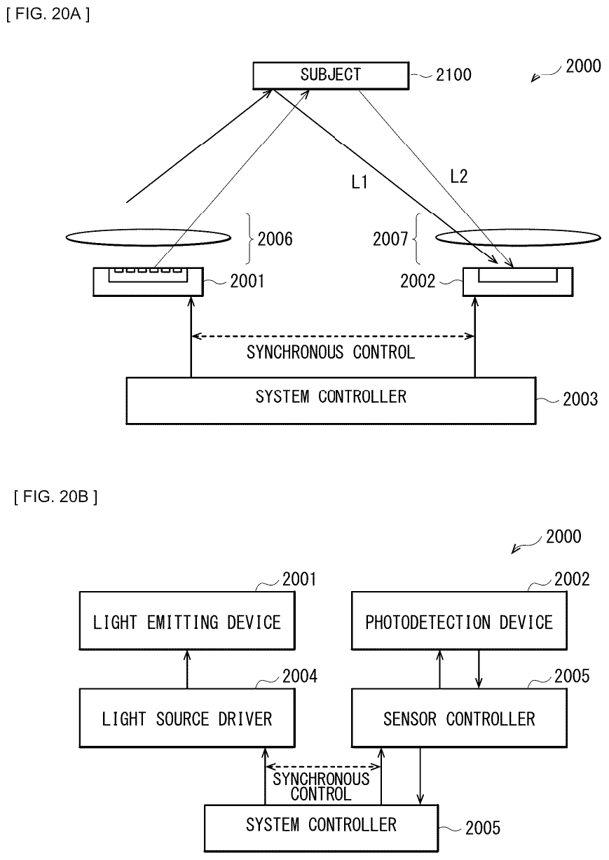

FIG. 20A schematically illustrates an example of an overall configuration of a photodetection system 2000 including the above-described imaging device 1 or the like. FIG. 20B illustrates an example of a circuit configuration of the photodetection system 2000. The photodetection system 2000 includes a light emitting device 2001 as a light source unit that emits infrared light L2 and a photodetection device 2002 as a light receiving unit that has a photoelectric converter. It is possible to use the imaging device 1 described above as the photodetection device 2002. The photodetection system 2000 may further include a system controller 2003, a light source driver 2004, a sensor controller 2005, a light source-side optical system 2006, and a camera-side optical system 2007.

The photodetection device 2002 is configured to detect light L1 and the light L2. The light L1 is light that is ambient light from outside, reflected on a subject (measurement target) 2100 (FIG. 20A). The light L2 is light that is emitted by the light emitting device 2001 and thereafter reflected by the subject 2100. The light L1 is visible light, for example, and the light L2 is infrared light, for example. The light L1 is detectable by the photoelectric converter in the photodetection device 2002. The light L2 is detectable in a photoelectric conversion region in the photodetection device 2002. It is possible to obtain image information of the subject 2100 from the light L1 and obtain distance information between the subject 2100 and the photodetection system 2000 from the light L2. It is possible to mount the photodetection system 2000 on, for example, an electronic apparatus such as a smartphone or a mobile object such as a vehicle. The light emitting device 2001 may include, for example, a semiconductor laser, a surface-emitting semiconductor laser, or a vertical-cavity surface-emitting laser (VCSEL). For example, an iTOF method may be adopted as a method of detecting the light L2 emitted from the light emitting device 2001 by the photodetection device 2002, but the present disclosure is not limited to this. The iTOF method allows the photoelectric converter to measure a distance to the subject 2100 by means of time-of-flight (Time-of-Flight: TOF), for example. For example, a structured light method or a stereo vision method may also be adopted as the method of detecting the light L2 emitted from the light emitting device 2001 by the photodetection device 2002. For example, the structure light method makes it possible to measure a distance between the photodetection system 2000 and the subject 2100 by projecting a predefined pattern of light onto the subject 2100 and analyzing a degree of distortion of that pattern. In addition, the stereo vision method makes it possible to measure the distance between the photodetection system 2000 and the subject 2100 by using, for example, two or more cameras and acquiring two or more images of the subject 2100 viewed from two or more different viewpoints. It is to be noted that the light emitting device 2001 and the photodetection device 2002 are synchronously controllable by the system controller 2003.

### 4. USAGE EXAMPLES

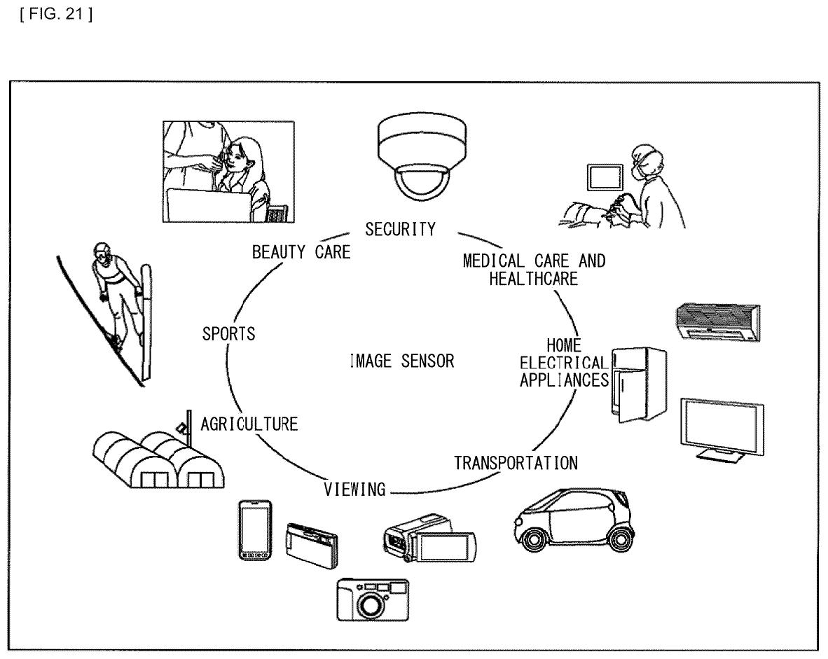

FIG. 21 illustrates an example of use of the imaging device (such as the imaging device 1) according to the embodiment described above, etc. For example, the above-described imaging device 1 is usable in various cases of sensing light such as visible light, infrared light, ultraviolet light, or X-rays, as described below.
Devices that photograph images offered for viewing, such as a digital camera or a mobile device with camera functions
Devices offered for transportation that are adapted to safe driving such as automatic stopping or recognition of the driver's condition, including, without limitation, in-vehicle sensors that photograph the front, rear, surroundings, and interior of an automobile; surveillance cameras that monitor, for example, traveling vehicles and roads; and ranging sensors that perform ranging of a space between vehicles or the like
Devices offered to home electrical appliances, such as televisions, refrigerators, or air conditioners, for photographing user gestures and operating devices on the basis of those gestures
Devices offered for medical care and healthcare purposes, including, without limitation, endoscopes and equipment that performs blood vessel imaging by receiving infrared light
Devices offered for security purposes, including, without limitation, surveillance cameras for crime prevention purposes, and cameras for person authentication purposes
Devices offered for beauty care including, without limitation, skin measuring instruments that photograph skin, and microscopes that photograph scalp
Devices offered for sports, including, without limitation, action cameras and wearable cameras for sports purposes
Devices offered for agriculture, including, without limitation, cameras for monitoring conditions of fields and crops

### 5. PRACTICAL APPLICATION EXAMPLES

### (Examples of Practical Application to Mobile Body)

The technology according to the present disclosure (present technology) is applicable to various products. For example, the technology according to the present disclosure may be implemented as a device to be mounted on any type of mobile bodies including, without limitation, an automobile, an electric vehicle, a hybrid electric vehicle, a motorcycle, a bicycle, a personal mobility, an airplane, a drone, a vessel, and a robot.

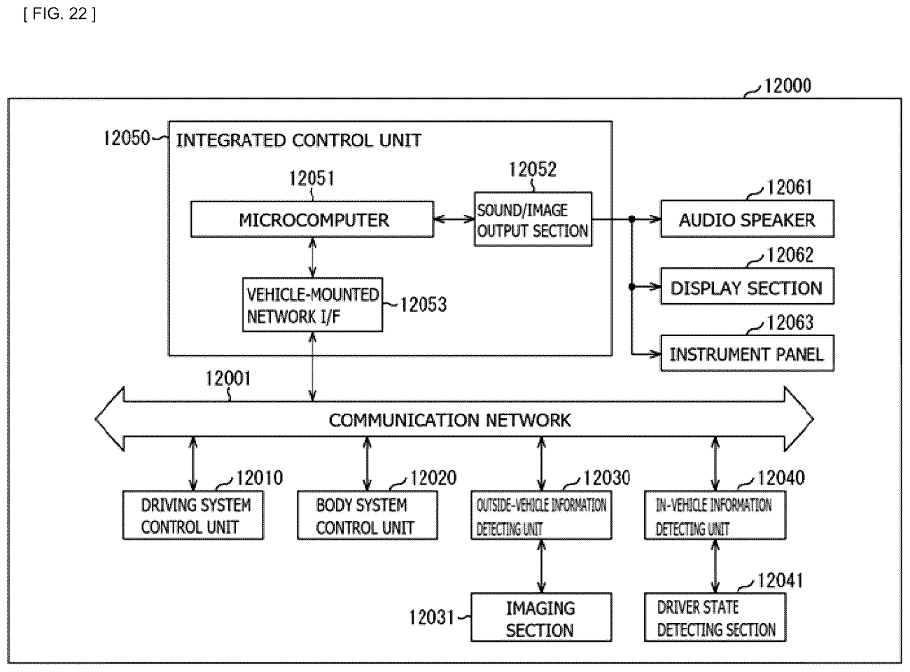

FIG. 22 is a block diagram depicting an example of schematic configuration of a vehicle control system as an example of a mobile body control system to which the technology according to an embodiment of the present disclosure can be applied.

The vehicle control system 12000 includes multiple electronic control units connected to each other via a communication network 12001. In the example depicted in FIG. 22, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 22, an audio speaker 12061, a display section 12062, and an instrument panel 12063 are illustrated as the output device. The display section 12062 may, for example, include at least one of an on-board display and a head-up display.

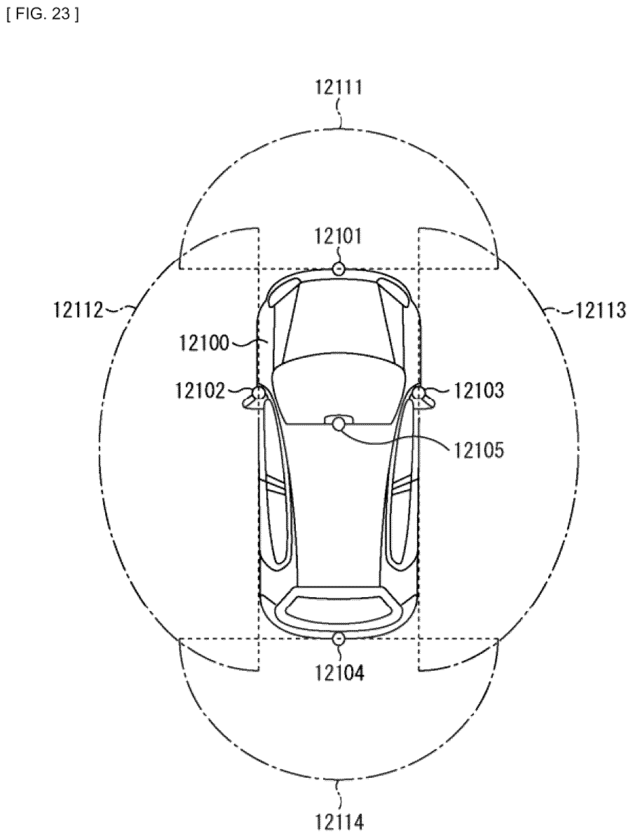

FIG. 23 is a diagram depicting an example of the installation position of the imaging section 12031.

In FIG. 23, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 23 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of multiple imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given above of an example of the mobile body control system to which the technology according to the present disclosure is applicable. The technology according to the present disclosure may be applied to the imaging section 12031 of the configurations described above. Specifically, the imaging device 1 or the like is applicable to the imaging section 12031. Applying the technology according to the present disclosure to the imaging section 12031 makes it possible to obtain images photographed with less noise and high definition. Therefore, highly accurate control utilizing the photographed image is allowed in the mobile body control system.

The present disclosure has been described above with reference to the embodiment, Modification examples 1 and 2, the application examples, the examples of use, and the practical application examples. The present technology is not limited to the embodiment, etc. described above, however, and various modifications may be made.

It is to be noted that the effects described herein are merely illustrative and are not limited to the description, and there may be other effects.

Note that it is possible for the present disclosure to have the following configurations. According to the present technology with the following configurations, second pixels that are each disposed in corresponding one of unit pixels are each disposed in corresponding one of the unit pixels to allow the second pixels to be equal to each other in distance from the center of the pixel array unit, on the basis of respective positions, in a pixel array unit, of the multiple unit pixels in which the respective second pixels are provided, in a planar view. This reduces the difference in output between the unit pixels disposed at equal distances from the center of the pixel array unit and makes shading characteristics uniform. Therefore, it becomes possible to improve image quality.
(1)

An imaging device including:
a semiconductor substrate including a first surface and a second surface that are opposed to each other, and including a pixel array unit in which multiple unit pixels are arranged in a matrix;
multiple first pixels each provided in corresponding one of the multiple unit pixels; and
multiple second pixels that are each provided in corresponding one of the multiple unit pixels and convert a smaller amount of charge per unit time than the multiple first pixels, in which
the multiple second pixels are each disposed in corresponding one of the unit pixels to allow the multiple second pixels to be equal to each other in distance from a center of the pixel array unit, on the basis of respective positions, in the pixel array unit, of the multiple unit pixels in which the respective second pixels are provided, in a planar view.
(2)

The imaging device according to (1) described above, in which the multiple second pixels each disposed in corresponding one of the multiple unit pixels are disposed point-symmetrically about the center of the pixel array unit, in a planar view.
(3)

The imaging device according to (1) or (2) described above, in which
the pixel array unit has an approximately rectangular shape, and is divided into four regions in a first direction and a second direction that are orthogonal in a planar view, the respective four regions having approximately equal areas, and
in the four regions, the multiple second pixels each disposed in corresponding one of the multiple unit pixels are disposed line-symmetrically about the first direction and the second direction.
(4)

The imaging device according to (3) described above, further including
multiple readout circuits that each read out charge generated in corresponding one of the multiple unit pixels, in which
the multiple readout circuits each include multiple transistors, and
the multiple transistors included in each of the multiple readout circuits are disposed line-symmetrically about the first direction and the second direction in the four regions.
(5)

The imaging device according to any one of (1) to (4) described above, in which
the multiple first pixels and the multiple second pixels each further include corresponding one of multiple first photoelectric converters and corresponding one of multiple second photoelectric converters, respectively, the multiple first photoelectric converters and the multiple second photoelectric converters generating charge according to an amount of received light by photoelectric conversion,
the multiple first photoelectric converters and the multiple second photoelectric converters are each embedded and provided in the semiconductor substrate, and
the multiple first photoelectric converters and the multiple second photoelectric converters are electrically isolated from each other by an element isolator extending between the first surface and the second surface of the semiconductor substrate.
(6)

The imaging device according to (5) described above, in which the element isolator includes an impurity injected region.
(7)

The imaging device according to (5) described above, in which the element isolator has a groove provided in the semiconductor substrate.
(8)

The imaging device according to 7, any one of (7) described above, in which the groove extends from the first surface toward the second surface and includes a bottom portion within the semiconductor substrate.
(9)

The imaging device according to (7) described above, in which the groove passes through from the first surface to the second surface.
(10)

The imaging device according to any one of (7) to (9) described above, in which an oxide film is embedded in the groove.
(11)

The imaging device according to any one of (7) to (9) described above, in which polysilicon is embedded in the groove.
(12)

The imaging device according to any one of (7) to (11) described above, in which tungsten is embedded in the groove.
(13)

The imaging device according to any one of (7) to (12) described above, in which a P-type solid-phase diffusion region is provided on a side wall of the groove.
(14)

The imaging device according to any one of (7) to (12) described above, in which an N-type solid-phase diffusion region is provided on a side wall of the groove.
(15)

An electronic apparatus including
an imaging device including
   a semiconductor substrate including a first surface and a second surface that are opposed to each other, and including a pixel array unit in which multiple unit pixels are arranged in a matrix,
   multiple first pixels each provided in corresponding one of the multiple unit pixels, and
   multiple second pixels that are each provided in corresponding one of the multiple unit pixels and convert a smaller amount of charge per unit time than the multiple first pixels, in which
   the multiple second pixels are each disposed in corresponding one of the unit pixels to allow the multiple second pixels to be equal to each other in distance from a center of the pixel array unit, on the basis of respective positions, in the pixel array unit, of the multiple unit pixels in which the respective second pixels are provided, in a planar view.

The present application claims the benefit of Japanese Priority Patent Application JP2021-181454 filed with the Japan Patent Office on Nov. 5, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An imaging device comprising:
a semiconductor substrate including a first surface and a second surface that are opposed to each other, and including a pixel array unit in which multiple unit pixels are arranged in a matrix;
multiple first pixels each provided in corresponding one of the multiple unit pixels; and
multiple second pixels that are each provided in corresponding one of the multiple unit pixels and convert a smaller amount of charge per unit time than the multiple first pixels, wherein
the multiple second pixels are each disposed in corresponding one of the unit pixels to allow the multiple second pixels to be equal to each other in distance from a center of the pixel array unit, on a basis of respective positions, in the pixel array unit, of the multiple unit pixels in which the respective second pixels are provided, in a planar view.

2. The imaging device according to claim 1, wherein the multiple second pixels each disposed in corresponding one of the multiple unit pixels are disposed point-symmetrically about the center of the pixel array unit, in a planar view.

3. The imaging device according to claim 1, wherein
the pixel array unit has an approximately rectangular shape, and is divided into four regions in a first direction and a second direction that are orthogonal in a planar view, the respective four regions having approximately equal areas, and
in the four regions, the multiple second pixels each disposed in corresponding one of the multiple unit pixels are disposed line-symmetrically about the first direction and the second direction.

4. The imaging device according to claim 3, further comprising
multiple readout circuits that each read out charge generated in corresponding one of the multiple unit pixels, wherein
the multiple readout circuits each include multiple transistors, and
the multiple transistors included in each of the multiple readout circuits are disposed line-symmetrically about the first direction and the second direction in the four regions.

5. The imaging device according to claim 1, wherein
the multiple first pixels and the multiple second pixels each further include corresponding one of multiple first photoelectric converters and corresponding one of multiple second photoelectric converters, respectively, the multiple first photoelectric converters and the multiple second photoelectric converters generating charge according to an amount of received light by photoelectric conversion,
the multiple first photoelectric converters and the multiple second photoelectric converters are each embedded and provided in the semiconductor substrate, and
the multiple first photoelectric converters and the multiple second photoelectric converters are electrically isolated from each other by an element isolator extending between the first surface and the second surface of the semiconductor substrate.

6. The imaging device according to claim 5, wherein the element isolator includes an impurity injected region.

7. The imaging device according to claim 5, wherein the element isolator has a groove provided in the semiconductor substrate.

8. The imaging device according to claim 7, wherein the groove extends from the first surface toward the second surface and includes a bottom portion within the semiconductor substrate.

9. The imaging device according to claim 7, wherein the groove passes through from the first surface to the second surface.

10. The imaging device according to claim 7, wherein an oxide film is embedded in the groove.

11. The imaging device according to claim 7, wherein polysilicon is embedded in the groove.

12. The imaging device according to claim 7, wherein tungsten is embedded in the groove.

13. The imaging device according to claim 7, wherein a P-type solid-phase diffusion region is provided on a side wall of the groove.

14. The imaging device according to claim 7, wherein an N-type solid-phase diffusion region is provided on a side wall of the groove.

15. An electronic apparatus comprising
an imaging device including
a semiconductor substrate including a first surface and a second surface that are opposed to each other, and including a pixel array unit in which multiple unit pixels are arranged in a matrix,
multiple first pixels each provided in corresponding one of the multiple unit pixels, and
multiple second pixels that are each provided in corresponding one of the multiple unit pixels and convert a smaller amount of charge per unit time than the multiple first pixels, wherein
the multiple second pixels are each disposed in corresponding one of the unit pixels to allow the multiple second pixels to be equal to each other in distance from a center of the pixel array unit, on a basis of respective positions, in the pixel array unit, of the multiple unit pixels in which the respective second pixels are provided, in a planar view.
